(19) United States
(12) Patent Application Publication
(10) Pub. No.: US 2025/0023005 A1
(43) Pub. Date: Jan. 16, 2025

(54) DISPLAY APPARATUS

(71) Applicant: LG Display Co., Ltd., Seoul (KR)

(72) Inventors: Jun Young JO, Paju-si (KR); Jae Kwang LEE, Paju-si (KR); Tae Yoon KIM, Paju-si (KR); Bung Goo KIM, Paju-si (KR); Hyoung Ho AHN, Paju-si (KR); Hee Won LEE, Paju-si (KR); Hye Sun JUNG, Paju-si (KR); Pyung Ho CHOI, Paju-si (KR)

(21) Appl. No.: 18/767,579

(22) Filed: Jul. 9, 2024

(30) Foreign Application Priority Data
Jul. 11, 2023 (KR) 10-2023-0089616

(51) Int. Cl. H01L 33/62; H01L 25/075; H01L 33/58

(52) U.S. Cl. CPC H01L 33/62; H01L 25/0753; H01L 33/58

(57) ABSTRACT

An embodiment discloses a display apparatus. The display apparatus includes a plurality of first electrodes and a contact electrode disposed on a substrate. The display apparatus includes a plurality of light-emitting elements disposed on the plurality of first electrodes. The display apparatus includes a first optical layer disposed between the plurality of light-emitting elements. The display apparatus includes a second electrode disposed on the plurality of light-emitting elements. The second electrode includes a first area disposed on the plurality of light-emitting elements and a second area extending outward from the first optical layer and electrically connected to the contact electrode. A plurality of signal wires connected to the plurality of first electrodes are provided, the second area of the second electrode comprises protruding portions extending to at least one of areas between the plurality of signal wires, and one of the protruding portions is connected to the contact electrode.

### CROSS-REFERENCE TO RELATED APPLICATION

This application claims priority to and the benefit of Korean Patent Application No. 10-2023-0089616, filed Jul. 11, 2023, the disclosure of which is incorporated herein by reference in its entirety.

### BACKGROUND

### Technical Field

The present disclosure relates to a display apparatus using an inorganic light-emitting diode as a light source.

### Description of the Related Art

Electroluminescent display devices may be roughly classified into organic light emitting display devices in which organic light emitting diodes (OLED) are disposed in pixels and inorganic light emitting display devices (hereinafter referred to as “display devices”) in which inorganic light emitting diodes (hereinafter referred to as “LED”) are disposed in pixels.

Since electroluminescent display devices display images using self-luminous elements, they do not require a separate light source, such as a backlight unit, and can be implemented in thin and diverse forms.

Organic light emitting display devices need to be designed to prevent penetration of oxygen and moisture because the penetration of moisture and oxygen can cause oxidation between the organic light emitting layer and the electrode.

As an example of inorganic light emitting display devices, micro LED display devices in which micro LEDs are disposed in pixels are attracting attention as a next-generation display device. The micro LEDs may be inorganic LEDs having sizes of 100 μm or less. The micro LEDs are manufactured through a separate semiconductor process, and transferred to the pixel location on the substrate for the display panel of the display device so that they can be disposed in each sub-pixel for each color.

### BRIEF SUMMARY

Each micro LED can be connected to the anode electrode and cathode electrode to receive power. However, there is a problem that a step occurs in the process of connecting the cathode electrode to a low potential voltage, and stress is concentrated in the area where the step occurs, causing cracks.

The present disclosure provides a display panel that reduces resistance by removing a portion where a cathode electrode overlaps a signal wire TL to reduce parasitic capacitance, and forming the cathode electrode at a portion with no signal wire TL to increase an area of the cathode electrode, and a display apparatus including the display panel.

The problems or limitations to be solved or addressed by the present disclosure are not limited to those mentioned above, and other problems or limitations not mentioned will be clearly understood by those skilled in the art from the following description.

A display apparatus according to one feature of the present disclosure includes: a plurality of first electrodes and a contact electrode disposed on a substrate; a plurality of light-emitting elements disposed on the plurality of first electrodes; a first optical layer disposed between the plurality of light-emitting elements; and a second electrode disposed on the plurality of light-emitting elements. The second electrode includes a first area disposed on the plurality of light-emitting elements and a second area extending outward from the first optical layer and electrically connected to the contact electrode. A plurality of signal wires connected to the plurality of first electrodes are provided, the second area of the second electrode comprises protruding portions extending to at least one of areas between the plurality of signal wires, and one of the protruding portions is connected to the contact electrode.

A display apparatus according to another feature of the present disclosure includes: a plurality of first electrodes disposed on a substrate; a plurality of light-emitting elements disposed on the plurality of first electrodes; a first optical layer disposed between the plurality of light-emitting elements; a second electrode disposed on the plurality of light-emitting elements; and a second optical layer covering the first optical layer, wherein the second electrode comprises a first area disposed on the plurality of light-emitting elements and a second area extending outward from the first optical layer, the second optical layer is disposed on the second area, the second area of the second electrode comprises protruding portions extending to at least one of areas between a plurality of signal wires, and one of the protruding portions is connected to a contact electrode for supplying the second electrode with a voltage.

According to the present disclosure, low-power driving may be possible by reducing parasitic capacitance occurring in an area where a cathode electrode and a signal wire overlap each other and suppressing an increase in the resistance of the cathode electrode.

The effects of the present disclosure are not limited to the above-mentioned effects, and other effects that are not mentioned will be apparently understood by those skilled in the art from the following description and the appended claims.

### BRIEF DESCRIPTION OF THE SEVERAL VIEWS OF THE DRAWINGS

The above and other objects, features and advantages of the present disclosure will become more apparent to those of ordinary skill in the art by describing exemplary embodiments thereof in detail with reference to the attached drawings, in which:

FIG. 1 is a diagram illustrating a display device according to one embodiment of the present specification;

FIG. 2 is an enlarged view of an area A of FIG. 1;

FIG. 3 is a diagram illustrating a partial area of a pixel;

FIG. 4 is a cross-sectional view taken along line I-I′ in FIG. 3;

FIG. 5 is a cross-sectional view taken along line II-II′ in FIG. 3;

FIG. 6 is a cross-sectional view taken along line III-III′ in FIG. 3;

FIG. 7 is a cross-sectional view illustrating an example in which a main light emitting element and a sub-light emitting element are electrically connected to a pixel driving circuit;

FIG. 8 is a diagram illustrating a display device according to another embodiment of the present specification;

FIG. 9 is a cross-sectional view taken along line IV-IV′ in FIG. 8;

FIG. 10 is a view illustrating a state in which stress is concentrated on a second electrode disposed in a through hole;

FIG. 11 is a first modified example of FIG. 8;

FIG. 12 is a second modified example of FIG. 8;

FIGS. 13A to 13F are views illustrating a method for manufacturing a display apparatus according to an embodiment of the present disclosure;

FIG. 14 is a modified example of a second electrode; and

FIG. 15 is a cross-sectional view taken along line V-V′ in FIG. 14.

### DETAILED DESCRIPTION

The advantages and features of the present disclosure and methods for accomplishing the same will be more clearly understood from embodiments described below with reference to the accompanying drawings. However, the present disclosure is not limited to the following embodiments but may be implemented in various different forms. Rather, the present embodiments will make the disclosure of the present disclosure complete and allow those skilled in the art to completely comprehend the scope of the present disclosure. The present disclosure is only defined within the scope of the accompanying claims.

The shapes, sizes, dimensions (e.g., length, width, height, thickness, radius, diameter, area, etc.), ratios, angles, numbers, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals generally denote like elements throughout the present specification. Further, in describing the present disclosure, detailed descriptions of known related technologies may be omitted to avoid unnecessarily obscuring the subject matter of the present disclosure.

The terms such as “including,” “having,” and “comprising” used herein are generally intended to allow other components to be added unless the terms are used with the term “only.” Any references to singular may include plural unless expressly stated otherwise.

Components are interpreted to include an ordinary error range even if not expressly stated.

When a positional or interconnected relationship is described between two components, such as “on top of,” “above,” “below,” “next to,” “connect or couple with,” “crossing,” “intersecting,” or the like, one or more other components may be interposed between them, unless “immediately” or “directly” is used.

When a temporal antecedent relationship is described, such as “after,” “following,” “next to,” “before,” or the like, it may not be continuous on a time base unless “immediately” or “directly” is used.

The terms “first,” “second,” and the like may be used to distinguish elements from each other, but the functions or structures of the components are not limited by ordinal numbers or component names in front of the components.

The following embodiments can be partially or entirely bonded to or combined with each other and can be linked and operated in technically various ways. The embodiments can be carried out independently of or in association with each other.

Hereinafter, various embodiments of the present disclosure will be described in detail with reference to the accompanying drawings.

A display device according to one embodiment of the present specification includes a display panel having a display area or screen on which an image is displayed, and a pixel driving circuit for driving pixels on the display panel. The display area includes a pixel area in which pixels are arranged. The pixel area includes a plurality of light emitting areas. A light emitting element is disposed in each of the light emitting areas. The pixel driving circuit may be built into the display panel.

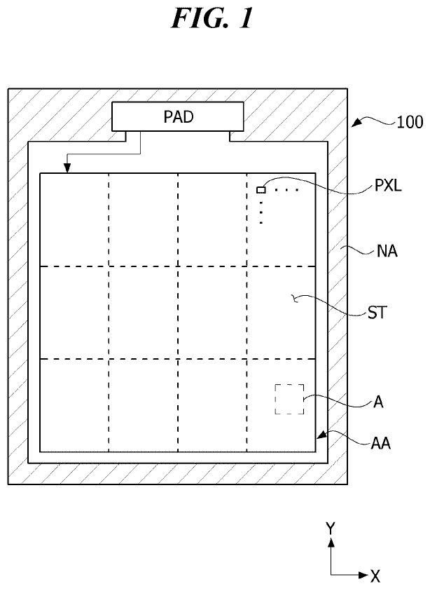

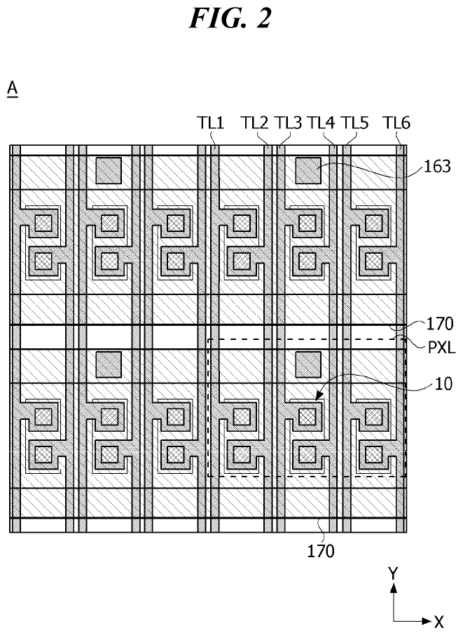

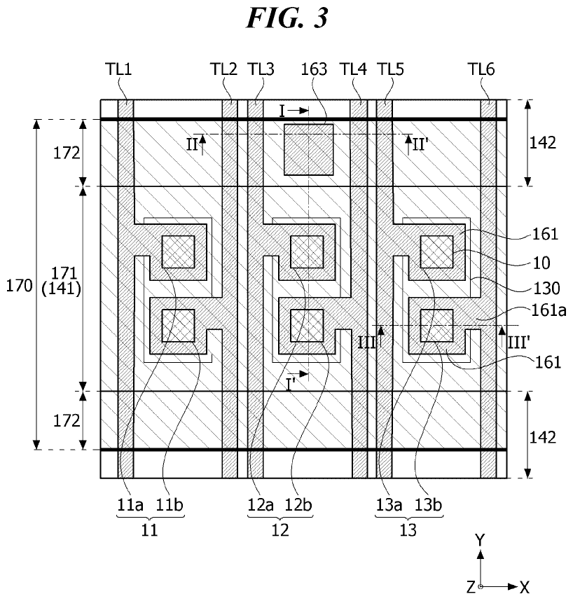

FIG. 1 is a diagram illustrating a display device according to one embodiment of the present specification; FIG. 2 is an enlarged view of an area A of FIG. 1; FIG. 3 is a diagram illustrating a partial area of a pixel.

Referring to FIGS. 1 and 2, a display device according to one embodiment of the present specification includes a display panel 100 that visually reproduces an input image. The display panel 100 may include a display area AA in which an image is displayed and a non-display area NA in which the image is not displayed. In the non-display area NA, various wire and driving circuits may be mounted and a pad portion PAD to which integrated circuits, printed circuits, etc., are connected may be disposed.

A plurality of light emitting elements 10 disposed in the display area AA to form pixels PXL may be micro-sized inorganic light emitting elements. The inorganic light emitting elements may be grown on a silicon wafer and then attached to the display panel through a transfer process.

The transfer process of the light emitting element 10 may be performed for each pre-divided area. In FIG. 1, the display area AA is divided into twelve transfer areas STs, but the size or number of divisions of the transfer areas is not limited thereto. The transfer process may be performed sequentially or simultaneously on first to twelfth transfer areas STs. In the transfer area ST, blue, green, and red light emitting elements 10 may be sequentially transferred, respectively.

In the non-display area NA, a data driving circuit or a gate driving circuit may be disposed, and wires for supplying control signals to control these driving circuits may be disposed. Here, the control signals may include various timing signals including a clock signal, an input data enable signal, and a synchronization signal, and may be received through the pad portion PAD.

The pixels PXL may be driven by a pixel driving circuit. The pixel driving circuit may receive a driving voltage, an image signal (digital signal), a synchronization signal synchronized with the image signal, etc., and output an anode voltage and a cathode voltage of the light emitting element 10 to drive a plurality of pixels. The driving voltage may be a high potential voltage (EVDD). The cathode voltage may be a low potential voltage (EVSS) commonly applied to the pixels. The anode voltage may be a voltage corresponding to the pixel data value of the image signal. The pixel driving circuit may be disposed in the non-display area NA or a lower portion of the display area AA.

Each of the pixels PXL may include a plurality of sub-pixels each having a different color. For example, the plurality of pixels may include a red sub-pixel in which the light emitting element 10 that emits light in a red wavelength is disposed, a green sub-pixel in which the light emitting element 10 that emits light in a green wavelength is disposed, and a blue sub-pixel in which the light emitting element 10 that emits light in a blue wavelength is disposed. The plurality of pixels may further include white pixels.

Referring to FIGS. 2 and 3, the plurality of pixels PXL may be sequentially arranged in a first direction (X-axis direction) and a second direction (Y-axis direction). Within the pixels of the display area AA, a plurality of sub-pixels of the same color may be arranged. For example, each of the plurality of pixels may include a first red sub-pixel in which a first-first light emitting element 11a that emits light in a red wavelength is disposed, a second red sub-pixel in which a second-first light emitting element 11b emits light in a red wavelength is disposed, a first green sub-pixel in which a first-second light emitting element 12a emitting light in a green wavelength is disposed, a second green sub-pixel in which a second-second light emitting element 12b emitting light in a green wavelength is disposed, a first blue sub-pixel in which a first-third light emitting element 13a emitting light in a blue wavelength is disposed, and a second blue sub-pixel in which a second-third light emitting element 13b emitting light in a blue wavelength is disposed. The first-first light emitting element 11a, the first-second light emitting element 12a, and the first-third light emitting element 13a may be interpreted as main light emitting elements. The second-first light emitting element 11b, the second-second light emitting element 12b, and the second-third light emitting element 13b may be interpreted as sub-light emitting elements. The first-first light emitting element 11a and the second-first light emitting element 11b are collectively referred as the first light emitting element 11, the first-second light emitting element 12a and the second-second light emitting element 12b are collectively referred as the second light emitting element 12, and the first-third light emitting element 13a and the second-third light emitting element 13b are collectively referred as the third light emitting element 13.

One sub-pixel includes one or more light emitting elements, and if one light emitting element becomes defective, the luminance of another light emitting element may be increased to adjust the luminance of the sub-pixel. However, it is not necessarily limited to thereto, and one sub-pixel may include only one light emitting element.

Each of a plurality of first electrodes 161 may be disposed in a lower portion of the light emitting element 10 and may be selectively connected to a plurality of signal wirings TL1 to TL6 by connection portions 161a. A high potential voltage may be applied to the pixel driving circuit through the signal wirings TL1 to TL6. The signal wirings TL1 to TL6 and the first electrode 161 may be formed as an electrode pattern integrated in an electrode patterning process.

Illustratively, the first signal wiring TL1 may be connected to an anode electrode of the first red sub-pixel, and the second signal wiring TL2 may be connected to an anode electrode of the second red sub-pixel. The third signal wiring TL3 may be connected to an anode electrode of the first green sub-pixel, and the fourth signal wiring TL4 may be connected to an anode electrode of the second green sub-pixel. The fifth signal wiring TL5 may be connected to an anode electrode of the first blue sub-pixel, and the sixth signal wiring TL6 may be connected to an anode electrode of the second blue sub-pixel. If one sub-pixel includes only one light emitting element, the number of signal wirings TL may be reduced by half.

A second electrodes 170 may be a cathode electrode that is arranged in each row to apply a cathode voltage to the light emitting element 10 continuously arranged in the first direction (X-axis direction). The plurality of second electrodes 170 may be arranged to be spaced apart from each other in the second direction (Y-axis direction). The plurality of second electrodes 170 may be connected to the cathode voltage through a contact electrode 163. Each of the plurality of second electrodes 170 may be electrically connected to the contact electrode 163. However, it is not necessarily limited thereto, and the second electrode 170 may include one electrode layer instead of being divided into a plurality of electrodes to function as a common electrode.

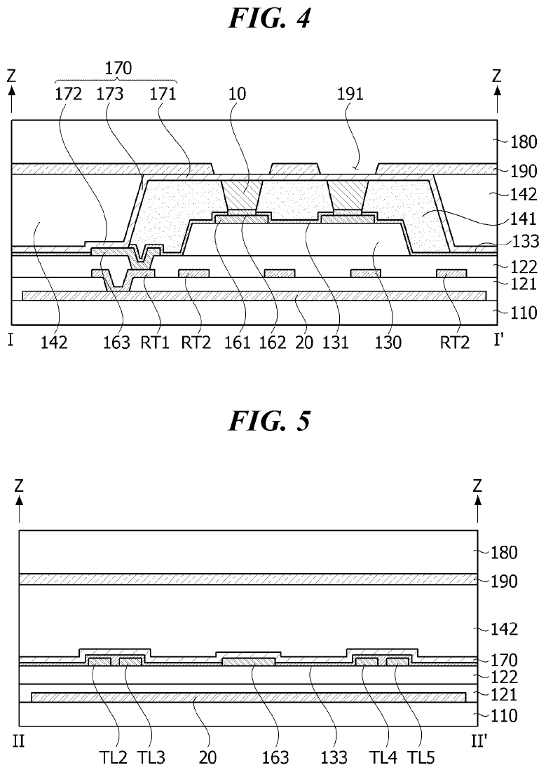

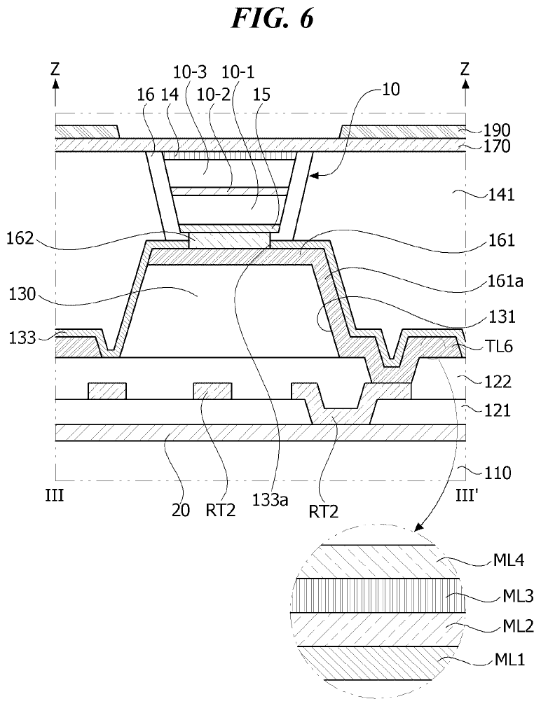

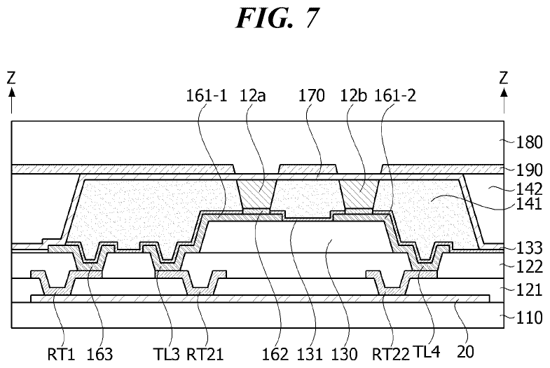

FIG. 4 is a cross-sectional view taken along line I-I′ in FIG. 3. FIG. 5 is a cross-sectional view taken along line II-II′ in FIG. 3. FIG. 6 is a cross-sectional view taken along line III-III′ in FIG. 3. FIG. 7 is a cross-sectional view showing an example in which two light emitting elements are connected to a pixel driving circuit.

Referring to FIGS. 3 to 5, a display device according to an embodiment includes a plurality of first electrodes 161 and a contact electrode 163 disposed on a substrate 110, a plurality of light emitting elements 10 disposed on a plurality of first electrodes 161, a first optical layer 141 disposed between the plurality of light emitting elements 10, and a second electrode 170 disposed on the plurality of light emitting elements 10.

The substrate 110 may be made of plastic with flexibility. For example, the substrate 110 may be made of a single-layer or multi-layer substrate of a material selected from polyimide, polyethylene terephthalate, polyethylene naphthalate, polycarbonate, polyethersulfone, and polyarylate, polysulfone, and cyclic-olefin copolymer, but is not limited thereto. For example, the substrate 110 may be a ceramic substrate or a glass substrate.

A pixel driving circuit 20 may be disposed in the display area AA on the substrate 110. The pixel driving circuit 20 may include a plurality of thin film transistors using an amorphous silicon semiconductor, a polycrystalline silicon semiconductor, or an oxide semiconductor.

The pixel driving circuit 20 may include at least one driving thin film transistor, at least one switching thin film transistor, and at least one storage capacitor. When the pixel driving circuit 20 includes a plurality of thin film transistors, it may be formed on the substrate 110 by a thin film transistor (TFT) manufacturing process. In embodiments, the pixel driving circuit 20 may be a collective term for a plurality of thin film transistors electrically connected to the light emitting element 10.

The pixel driving circuit 20 may be a driving driver (which may be also simply referred as a driver) manufactured using a metal-oxide-silicon field effect transistor (MOSFET) manufacturing process on a single crystal semiconductor substrate 110. The driving driver may include a plurality of pixel driving circuits to drive a plurality of sub-pixels. When the pixel driving circuit 20 is implemented as a driving driver, after an adhesive layer is disposed on the substrate 110, the driving driver may be mounted on the adhesive layer by a transfer process.

A buffer layer 121 covering the pixel driving circuit 20 may be disposed on the substrate 110. The buffer layer 121 may be made of an organic insulating material, for example, photosensitive photo acryl or photosensitive polyimide, but is not limited thereto.

The buffer layer 121 may be used by stacking an inorganic insulating material, for example, silicon nitride (SiNₓ) or silicon oxide (SiO₂) in a multiple layers, and may be used by stacking an organic insulating material and an inorganic insulating material in multiple layers.

An insulating layer 122 may be disposed on the buffer layer 121. The insulating layer 122 may be made of an organic insulating material, for example, photosensitive photo acryl or photosensitive polyimide, but is not limited thereto. Connection wirings RT1 and RT2 may be disposed on the buffer layer 121. The connection wirings RT1 and RT2 may be connected by the corresponding signal wirings TL1 to TL6 or may be connected to the signal wirings TL1 to TL6. The connection wirings RT1 and RT2 may include a plurality of wiring patterns disposed on different layers with one or more insulating layers interposed therebetween. The wiring patterns disposed on the different layers may be electrically connected via contact holes through which the insulating layers are passed.

A plurality of bank patterns 130 may be disposed on the insulating layer 122. At least one light emitting element 10 may be disposed on each bank pattern 130. For example, a first light emitting element 11 may be disposed on a first bank pattern 130, a second light emitting element 12 is disposed on a second bank pattern 130, and a third light emitting element 13 may be disposed on a third bank pattern 130.

The bank patterns 130 may be made of an organic insulating material, for example, photosensitive acryl or photosensitive polyimide, but is not limited thereto. The bank pattern 130 may guide a position to which the light emitting element 10 is to be attached in the transfer process of the light emitting element 10. The bank pattern 130 may be omitted.

A solder pattern 162 may be disposed on the first electrode 161. The solder pattern 162 may be made of indium (In), tin (Sn), or an alloy thereof, but is not limited thereto.

The plurality of light emitting elements 10 may each be mounted on the solder pattern 162. One pixel may include light emitting elements 10 of three colors. The first light emitting element 11 may be a red light emitting element, the second light emitting element 12 may be a green light emitting element, and the third light emitting element 13 may be a blue light emitting element. Two light emitting elements may be mounted in each sub-pixel.

A first optical layer 141 may cover the plurality of light emitting elements 10 and the bank pattern 130. Accordingly, the first optical layer 141 may cover between the plurality of light emitting elements 10 and between the plurality of bank patterns 130. The first optical layer 141 may extend in the first direction (X-axis direction) and be spaced apart in the second direction (Y-axis direction) to be separated between rows of pixels.

The first optical layer 141 may include an organic insulating material in which fine metal particles such as titanium dioxide particles are dispersed. Light emitted from the plurality of light emitting elements 10 may be scattered by fine metal particles dispersed in the first optical layer 141 to be emitted externally.

The second electrode 170 may be disposed on the plurality of light emitting elements 10. The second electrode 170 may be commonly connected to the plurality of pixels PXL. The second electrode 170 may be a thin electrode through which light is transmitted. The second electrode 170 may be a transparent electrode material, for example, indium tin oxide (ITO), but is not necessarily limited thereto.

The second electrode 170 may extend in the first direction (X-axis direction) and be spaced apart in the second direction (Y-axis direction). The second electrode 170 may include a first area 171 disposed on a top surface of the light emitting element 10 and a top surface of the first optical layer 141, a second area 172 in contact with the contact electrode 163 and electrically connected to the contact electrode 163, and a third area 173 disposed on a side of the first optical layer 141 and connecting the first area 171 and the second area 172.

On a plane, each of the plurality of second electrodes 170 may overlap the first optical layer 141, and the second area 172 may cover a plane outside the first optical layer 141.

The second optical layer 142 may be an organic insulating material surrounding the first optical layer 141. The second optical layer 142 may be disposed on the insulating layer 122 together with the first optical layer 141. The first optical layer 141 and the second optical layer 142 may include the same material (e. g., siloxane). For example, the first optical layer 141 may be siloxane containing titanium oxide (TiOx), and the second optical layer 142 may be siloxane not containing titanium oxide (TiOx). However, it is not necessarily limited to thereto, and the first optical layer 141 and the second optical layer 142 may be formed of the same material or may be formed of different materials.

According to an embodiment, since the second area 172 of the second electrode 170 is connected to the contact electrode 163 in an overall flat state, excessive stress is not concentrated at the point of connection with the contact electrode 163. Therefore, it is possible to effectively prevent cracks from occurring in the second electrode 170.

The second optical layer 142 may cover the second area 172 and the third area 173 of the second electrode 170. The top surface of the second optical layer 142 and the top surface of the first area 171 of the second electrode 170 may be coplanar. In other words, the first optical layer 141 and the second optical layer 142 may function as planarization layers. As a result, a pattern of a black matrix 190 may be easily formed on the first optical layer 141 and the second optical layer 142 because there is no step on the surface where the black matrix 190 is formed. However, it is not necessarily limited to thereto, and the top surfaces of the second optical layer 142 and the second electrode 170 may have different heights.

The black matrix 190 may be an organic insulating material to which black pigment is added. Beneath the black matrix 190, the second electrode 170 may be in contact with the contact electrode 163. A transmission hole 191 may be formed between the patterns of the black matrix 190, through which light emitted from the light emitting element 10 is externally emitted. By the black matrix 190, the problem of mixing of light emitted from neighboring light emitting elements 10 by the first optical layer 141 may be improved.

The cover layer 180 may be an organic insulating material for covering the black matrix 190 and the second electrode 170. In FIG. 3, the configuration of the black matrix 190 and the cover layer 180 is omitted.

The contact electrode 163 is electrically connected to the first connection wiring RT1 disposed on a lower portion thereof, and the first connection wiring RT1 may be connected to the pixel driving circuit 20. Accordingly, the second electrode 170 may be applied with a cathode voltage through the contact electrode 163. The first electrode 161 may be electrically connected to the second connection wiring RT2. This will be described later.

Referring to FIG. 5, the contact electrode 163 and signal wirings TL1 to TL6 may be disposed on the same plane. The pixel driving circuit 20 may be disposed on a lower portion of the contact electrode 163 and the signal wirings TL1 to TL6. When the pixel driving circuit 20 is a driving driver, a plurality of driving drivers may be disposed in the display panel.

A passivation layer 133 may expose the contact electrode 163 so that the contact electrode 163 and the second electrode 170 are electrically connected. In addition, the passivation layer 133 may insulate the signal wirings TL2 to TL5 and the second electrode 170.

Referring to FIG. 6, a connection portion 161a of the first electrode 161 extends to one side surface 131 of the bank pattern 130 and is electrically connected to the connection wiring RT2 disposed on the insulating layer 122.

The first electrode 161, the connection portion 161a, the signal wiring TL, and/or the connection wirings RT1 and RT2 may include a single or multi-layer metal layer selected from titanium (Ti), molybdenum (Mo), and aluminum (Al). The first electrode 161, the connection portion 161a, the signal wiring TL and/or the connection wirings RT1 and RT2 may be formed in a multi-layer structure including a first layer ML1, a second layer ML2, a third layer ML3, and a four layer ML4.

The first layer ML1 and the third layer ML3 may include titanium (Ti) or molybdenum (Mo). The second layer ML2 may include aluminum (Al). The fourth layer ML4 may include a transparent conductive oxide layer such as indium tin oxide (ITO) or indium zinc oxide (IZO), which has good adhesion to the solder pattern 162, corrosion resistance, and acid resistance.

The first layer ML1, the second layer ML2, the third layer ML3, and the fourth layer ML4 may be sequentially deposited and then patterned by performing a photolithography process and an etching process.

The passivation layer 133 may be disposed on the first electrode 161 and the signal wiring TL and may include an opening hole 133a exposing the solder pattern 162.

The light emitting element 10 may include a first conductive type semiconductor layer 10-1, an active layer 10-2 disposed on the first conductive type semiconductor layer 10-1, and a second conductive type semiconductor layer 10-3 disposed on the active layer 10-2. A first driving electrode 15 may be disposed on a lower portion of the first conductive type semiconductor layer 10-1, and a second driving electrode 14 may be disposed on an upper portion of the second conductive type semiconductor layer 10-3.

The light emitting element 10 may be formed on a silicon wafer using methods such as metal organic chemical vapor deposition (MOCVD), chemical vapor deposition (CVD), plasma-enhanced chemical vapor deposition (PECVD), molecular beam epitaxy (MBE), hydride vapor phase epitaxy (HVPE), sputtering, and the like.

The first conductivity type semiconductor layer 10-1 may be implemented as a compound semiconductor such as Group III-V, Group II-VI, etc., and may be doped with a first dopant. The first conductive type semiconductor layer 10-1 may be formed of any one or more of the semiconductor materials having a composition formula of Alₓ₁In_{y1}Ga_{(1-x1-y1)}N(0≤x1≤1, 0≤y1≤1, 0≤x1+y1≤1), InAlGaN, AlGaAs, GaP, GaAs, and AlGaInP, but is not limited thereto. When the first dopant is an n-type dopant such as Si, Ge, Sn, Se, Te, etc., the first conductive type semiconductor layer 10-1 may be an n-type nitride semiconductor layer. However, when the first dopant is a p-type dopant, the first conductive type semiconductor layer 10-1 may be a p-type nitride semiconductor layer.

The active layer 10-2 is a layer in which electrons (or holes) injected through the first conductive type semiconductor layer 10-1 meet holes (or electrons) injected through the second conductive type semiconductor layer 10-3. The active layer 10-2 may generate light that transitions to lower energy levels as the electrons and holes are recombined, and has a corresponding wavelength.

The active layer 10-2 may have any one of a single well structure, a multi-well structure, a single quantum well structure, a multi quantum well (MQW) structure, a quantum dot structure, or a quantum line structure, and the structure of the active layer 10-2 is not limited thereto. The active layer 10-2 may generate light in a visible light wavelength band. Illustratively, the active layer 10-2 may output light in any one of blue, green, and red wavelength bands.

The second conductive type semiconductor layer 10-3 may be disposed on the active layer 10-2. The second conductive type semiconductor layer 10-3 may be implemented as a compound semiconductor such as Group III-V, Group II-VI, etc., and the second conductive type semiconductor layer 10-3 may be doped with a second dopant. The second conductive type semiconductor layer 10-3 may be formed from semiconductor materials having a composition formula of Inₓ₂Alₓ₂Ga1_{-x-2+y}2N (0≤x2≤1, 0≤y2≤1, 0≤x2+y2≤1) or materials selected from AlInN, AlGaAs, GaP, GaAs, GaAsP, and AlGaInP. When the second dopant is a p-type dopant such as Mg, Zn, Ca, Sr, Ba, etc., the second conductive type semiconductor layer 10-3 doped with the second dopant may be a p-type semiconductor layer. When the second dopant is an n-type dopant, the second conductive type semiconductor layer 10-3 may be an n-type nitride semiconductor layer.

A reflective layer 16 may be disposed on a side surface and lower portion of the light emitting element 10. The reflective layer 16 may have a structure in which a reflective material is dispersed in a resin layer, but is not necessarily limited to thereto. Illustratively, the reflective layer 16 may be manufactured as a reflector of various structures. Light emitted from the active layer 10-2 by the reflective layer 16 may be reflected upward to increase light extraction efficiency.

Although the embodiment is described as a vertical structure in which the driving electrodes 14 and 15 are disposed on the upper and lower portion of the light-emitting structure, the light-emitting element may have a light-emitting structure of a lateral structure or a flip chip structure in addition to the vertical structure.

Referring to FIG. 7, a main light emitting element 12a and sub-light emitting element 12b of the sub-pixel may be disposed on the bank pattern 130. The second light emitting element 12 will be illustratively described. A first-first electrode 161-1 connected to the main light emitting element 12a may extend to one side surface of the bank pattern 130 to be electrically connected to the first-second connection wiring RT21 disposed on a lower portion thereof. The second-first electrode 161-2 connected to the sub-light emitting element 12b may extend to the other side surface of the bank pattern 130 to be electrically connected to the second-second connection wiring RT22 disposed on a lower portion thereof.

The pixel driving circuit 20 may apply an anode voltage to the main light emitting element 12a by the first-second connection wiring RT21, and may apply an anode voltage to the sub-light emitting element 12b by the second-second connection wiring RT22. The pixel driving circuit 20 may apply a cathode voltage to the main light emitting element 12a and the sub-light emitting element 12b through the first connection wiring RT1 and the second electrode 170.

The pixel driving circuit 20 may adjust luminance by driving only the main light emitting element 12a, or may adjust luminance by simultaneously driving the main light emitting element 12a and the sub-light emitting element 12b. If the main light emitting element 12a is darkened, the luminance may be adjusted by driving only the sub-light emitting element 12b.

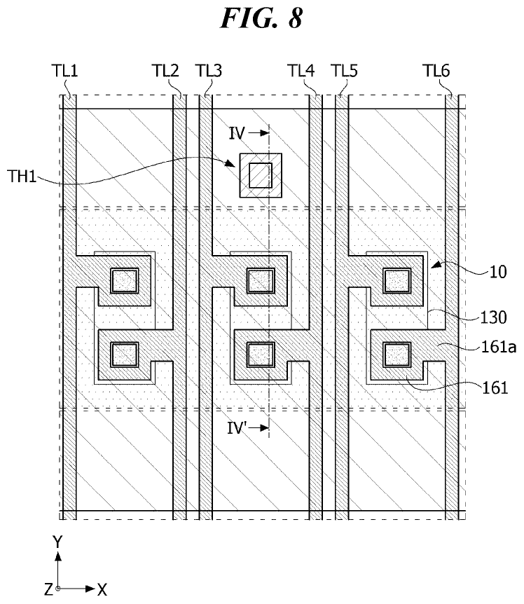

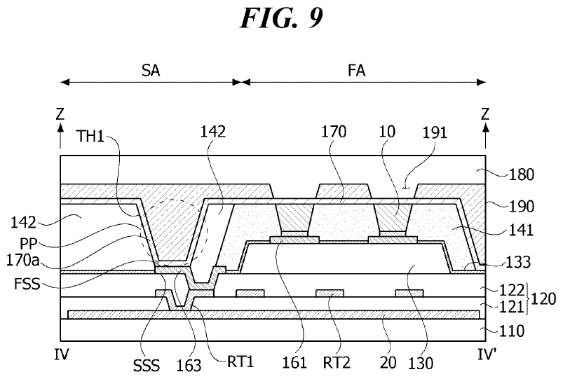

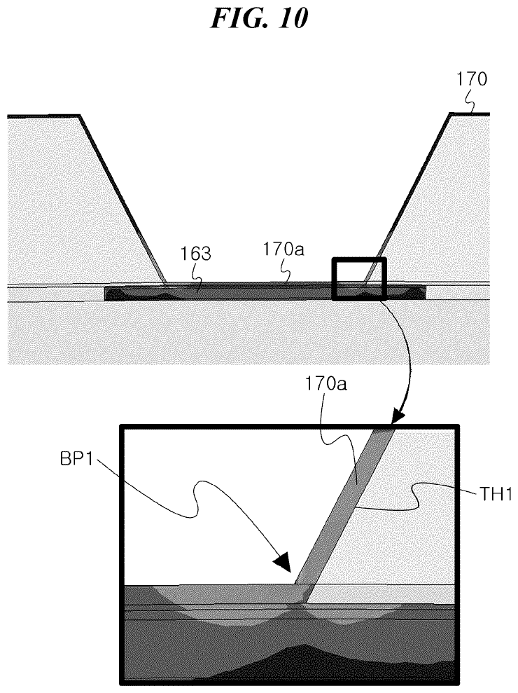

FIG. 8 is a diagram illustrating a display device according to another embodiment of the present specification. FIG. 9 is a cross-sectional view taken along line IV-IV′ in FIG. 8. FIG. 10 is a view illustrating a state in which stress is concentrated on a second electrode disposed in a through hole.

Referring to FIGS. 8 and 9, the second electrode 170 may be electrically connected to the contact electrode 163 via a contact hole TH1 formed in the second optical layer 142. The second optical layer 142 may include the contact hole TH1 exposing the contact electrode 163. The second electrode 170 may be inserted into the contact hole TH1 of the second optical layer 142 and may be in contact with an upper surface of the contact electrode 163. The contact hole TH1 may be formed in an outer area of the pixel.

Referring to FIG. 9, the contact electrode 163 is located in an area (e.g., a second area SA) spaced apart from the plurality of first electrodes 161 when seen from a plan view. The plurality of first electrodes 161 are disposed in a first area FA adjacent to the second area SA. The contact electrode 163 has a first surface FSS and a second surface SSS opposite the first surface FSS. Here, the first surface FSS of the contact electrode 163 directly contacts the second electrode 170. The second surface SSS of the contact electrode 163 faces the substrate 110. The second surface SSS of the contact electrode 163 directly contacts connection wiring RT1. As shown, the second electrode 170 extends from a light-emitting element 10 of the plurality of light-emitting elements in the first area FA to the second area SA where the contact electrode 163 is located.

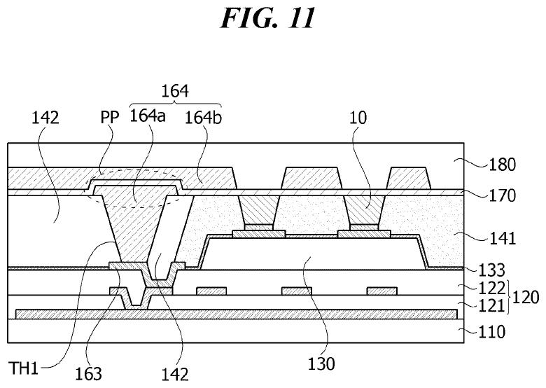

A protruding portion PP of the second electrode 170 may refer to as a portion of the second electrode 170 that protrudes in a selected direction. The protruding portion PP of the second electrode 170 may also refer to area 173 and area 172 of the second electrode 170 that protrudes toward the direction of the substrate 110. The protruding portion PP of the second electrode 170 may indicate the part 170a of the second electrode 170. The direction where the protruding portion PP protrudes can be in a direction opposite of the substrate 110 as shown in FIG. 11. This will be explained in more detail with respect to FIG. 11.

Referring to FIG. 10, since the second electrode 170 is relatively thin and the contact hole TH1 is formed deeper than the thickness of the second electrode 170, a stress concentration area BP1 may occur in a part 170a of the second electrode 170 formed on a side of the contact hole TH1. Accordingly, cracks may be likely to occur in the part 170a of the second electrode 170 formed around the contact hole TH1. In some embodiments, as described previously, the part 170a of the second electrode 170 is referred to as the protruding portion of the second electrode 170.

However, as described with reference to FIG. 4, when the second electrode 170 is connected to the contact electrode 163 in a flat and extended state instead of forming the contact hole TH1, it is possible to prevent excessive stress from being applied to the second electrode 170. Accordingly, it is possible to prevent cracks from occurring in the second electrode 170.

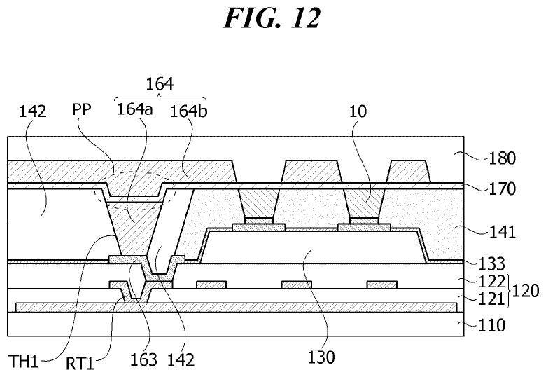

FIG. 11 is a first modified example of FIG. 8. FIG. 12 is a second modified example of FIG. 8.

Referring to FIG. 11, the contact hole TH1 may be filled with a separate through electrode 164. The through electrode 164 may include various conductive materials that can be filled in the contact hole TH1. Since the second electrode 170 is disposed on the through electrode 164, it is formed relatively flat, thereby preventing excessive stress from occurring.

The through electrode 164 includes a first portion 164a and a second portion 164b. For example, the first portion 164a of the through electrode is disposed beneath the protruding portion PP of the second electrode 170 and the second portion 164b of the through electrode 164 is disposed above the protruding portion PP of the second electrode 170. Here, the first portion 164a of the through electrode 164 directly contacts the first surface FSS of the contact electrode 163.

Referring to FIG. 12, the through electrode 164 may not completely fill the contact hole TH1 but only up to a certain height. According to such a structure, the depth at which the second electrode 170 is inserted into the contact hole TH1 may be relatively low. Accordingly, the step of the second electrode 170 may be reduced, thereby reducing the probability of cracks.

Similar to FIG. 11, the through electrode 164 includes a first portion 164a and a second portion 164b. For example, the first portion 164a of the through electrode is disposed beneath the protruding portion PP of the second electrode 170 and the second portion 164b of the through electrode 164 is disposed above the protruding portion PP of the second electrode 170. Here, the first portion 164a of the through electrode 164 directly contacts the first surface FSS of the contact electrode 163.

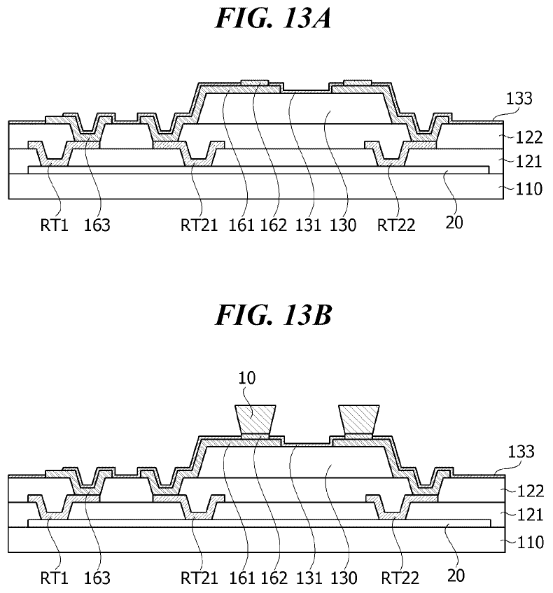

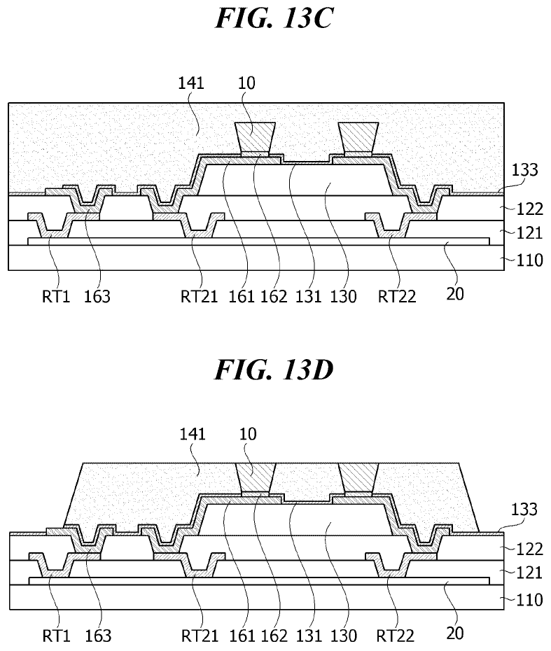

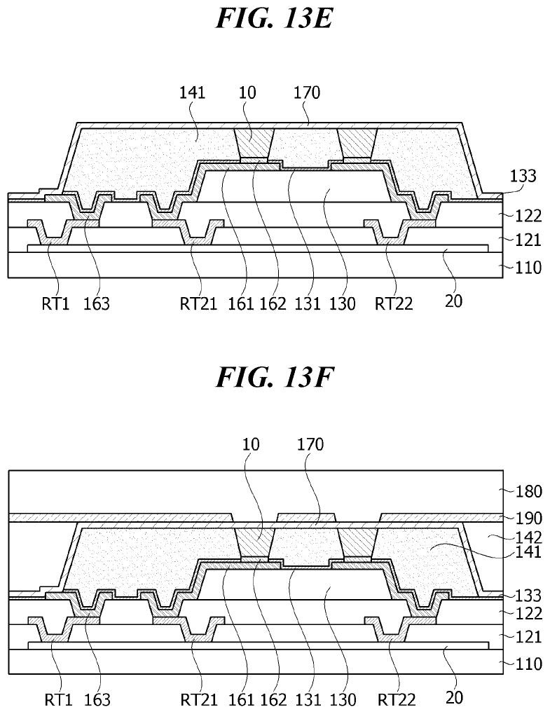

FIGS. 13A to 13F are views illustrating a method for manufacturing a display apparatus according to an embodiment of the present disclosure.

Referring to FIG. 13A, a pixel driving circuit 20 may be formed on the substrate 110, and the buffer layer 121 may be formed on the pixel driving circuit 20. The pixel driving circuit 20 may receive a driving voltage, an image signal (digital signal), a synchronization signal synchronized with the image signal, and the like, and output the anode voltage and the cathode voltage of the light-emitting element 10, thereby driving a plurality of pixels. The pixel driving circuit 20 may be disposed in the non-display area NA or below the display area AA.

Subsequently, the connection wires RT1, RT21 and RT22 may be formed on the buffer layer 121 and then the insulating layer 122 may be formed. The connection wires RT1, RT21 and RT22 may be electrically connected to the pixel driving circuit 20 by passing through the buffer layer 121. In order to drive each pixel, the number of connection wires RT1, RT21 and RT22 and the number of stacks of the connection wires RT1, RT21 and RT22 may be varied. Accordingly, the number of stacks of the connection wires RT1, RT21 and RT22 and the insulating layer 122 may be two or more layers.

A bank pattern 130 may be formed on the insulating layer 122 to select a location where the light-emitting element 10 is transferred. The bank pattern 130 may be made of an organic insulating material, for example, photosensitive photo acryl or photosensitive polyimide, but is not limited thereto. The bank pattern 130 may guide a location where the light-emitting element 10 is to be attached during the transfer process of the light-emitting element 10. However, the bank pattern 130 may be omitted.

An electrode material may be applied on the insulating layer 122 and the bank pattern 130 and then patterned to form a plurality of first electrodes 161 and a contact electrode 163. The plurality of first electrodes 161 are areas where the light-emitting element 10 is disposed, and the contact electrode 163 is an area where the second electrode 170 is electrically connected. Subsequently, a passivation layer 133 may be formed in electrode areas including the area where the plurality of first electrodes 161 and the contact electrode 163 are formed.

A solder pattern 162 may be formed on the first electrode 161. The solder pattern 162 may be made of indium (In), tin (Sn), or an alloy thereof, but is not limited thereto.

Referring to FIG. 13B, the plurality of light-emitting elements 10 may be transferred onto the solder pattern 162, respectively. One pixel may include light-emitting elements 10 of three colors. A first light-emitting element may be a red light-emitting element, a second light-emitting element may be a green light-emitting element, and a third light-emitting element may be a blue light-emitting element. Two light-emitting elements may be mounted in each sub-pixel.

The transfer method is not particularly limited. That is, the light-emitting element 10 grown on the semiconductor growth substrate may be first transferred to the transfer substrate and then secondarily transferred to the panel substrate, or the light-emitting element 10 grown on the semiconductor growth substrate may be directly transferred to the panel substrate.

Referring to FIGS. 13C and 13D, a first optical layer 141 may be entirely formed on the substrate 110 and then patterned so that the top surface of the light-emitting element 10 and the contact electrode 163 are exposed. A remaining portion of the first optical layer 141 may be removed except for an area sufficient to cover the light-emitting element 10 and the bank pattern 130. Accordingly, the first optical layer 141 may cover between the plurality of light-emitting elements 10 and between the plurality of bank patterns 130. At this time, the top surface of the light-emitting element 10 may be exposed to the top of the first optical layer 141.

The first optical layer 141 may include an organic insulating material in which fine metal particles such as titanium dioxide particles are dispersed. Light emitted from the light-emitting elements 10 may be scattered by the fine metal particles dispersed in the first optical layer 141 and then emitted.

Referring to FIG. 13E, a second electrode 170 may be formed on the plurality of light-emitting elements 10. The second electrode 170 may be commonly connected to all pixels. The second electrode 170 may be a thin metal electrode that transmits light. The second electrode 170 may be a transparent electrode material, for example, indium tin oxide (ITO), but is not necessarily limited thereto.

The second electrode 170 may be divided to be disposed in each pixel row through patterning. The plurality of divided second electrodes 170 may be electrically connected to the contact electrode 163.

Referring to FIG. 13F, a second optical layer 142 may be formed to surround the first optical layer 141. In this process, the second optical layer 142 may cover a portion where the second electrode 170 is connected to the contact electrode 163.

The second optical layer 142 may be disposed on the insulating layer 122 together with the first optical layer 141. The first optical layer 141 and the second optical layer 142 may include the same material (for example, siloxane). For example, the first optical layer 141 may be siloxane containing titanium oxide (TiOx), and the second optical layer 142 may be siloxane containing no titanium oxide (TiOx).

Subsequently, a black matrix 190 may be formed on the second electrode 170 and the second optical layer 142, and a cover layer 180 may be formed on the black matrix 190.

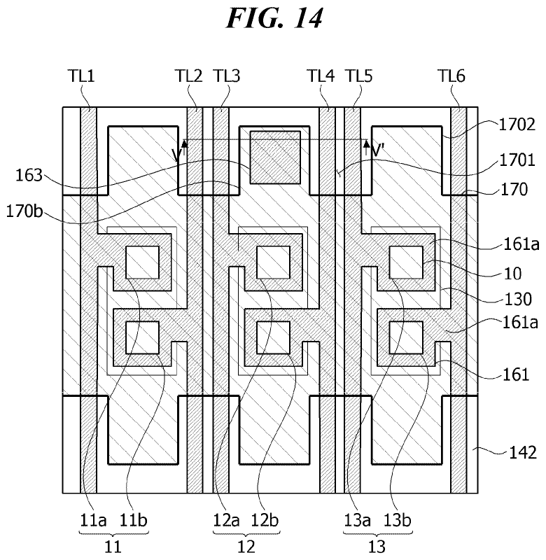

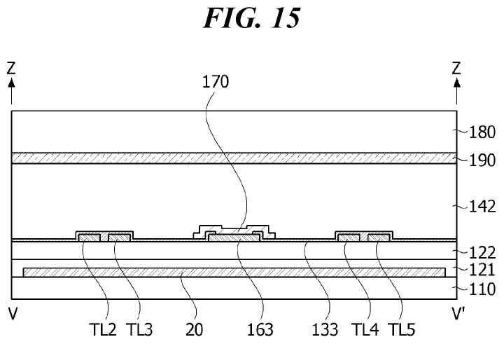

FIG. 14 is a modified example of a second electrode. FIG. 15 is a cross-sectional view taken along line V-V′ in FIG. 14.

Referring to FIG. 14, a portion of the second electrode 170 is removed not to overlap the signal wire TL on a plane, so that at least one concave portion 1701 and at least one convex portion 1702 may be alternately formed. Any one of such convex portions 1702 may be connected to the contact electrode 163. Additionally, a plurality of concave portions 1701 and a plurality of convex portions 1702 may be alternately formed. Any one of such convex portions 1702 may be connected to the contact electrode 163. FIG. 14 illustrates an embodiment in which the plurality of convex portions 1702 are formed and one of the convex portions 1702 is connected to the contact electrode 163. However, in addition to the convex portion 1702 connected to the contact electrode 163, the remaining convex portions 1702 may be selectively formed.

Referring to FIG. 5, only the passivation layer 133 with a low thickness is disposed between the signal wire TL and the second electrode 170, so that the capacitance is formed to be higher than that of other areas, causing interference with a driving signal. Referring to FIGS. 14 and 15, when a portion overlapping with the signal wire TL is removed from a second area (that is, the second area 172 shown in FIG. 3) 172 where the second electrode 170 is disposed outside the first optical layer 141, parasitic capacitance between the second electrode 170 and the signal wire TL can be reduced. Additionally, the second electrode 170 may be formed in a portion with no signal wire TL in the second area 172 (see FIG. 3), thereby increasing the area of the second electrode 170 and reducing resistance.

A display apparatus according to an embodiment of the present disclosure may be applied to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an electronic book, a portable multimedia player (PMP), a personal digital assistant (PDA), an MP3 player, a mobile medical device, a desktop personal computer (PC), a laptop personal computer (PC), a netbook computer, a workstation, a navigation, a vehicle display device, a theater display device, a television, a wallpaper device, a signage device, a game device, a notebook, a monitor, a camera, a camcorder, a home appliance, or the like. Additionally, the display apparatus according to one or more embodiments of the present disclosure may be applied to an organic light-emitting lighting device or an inorganic light-emitting lighting device.

According to one or more embodiments of the present disclosure, a display apparatus may be described as follows.

According to one or more embodiments of the present disclosure, a display apparatus may include a plurality of first electrodes and a contact electrode disposed on a substrate; a plurality of light-emitting elements disposed on the plurality of first electrodes; a first optical layer disposed between the plurality of light-emitting elements; and a second electrode disposed on the plurality of light-emitting elements, wherein the second electrode comprises a first area disposed on the plurality of light-emitting elements and a second area extending outward from the first optical layer and electrically connected to the contact electrode, a plurality of signal wires connected to the plurality of first electrodes are provided, the second area of the second electrode comprises protruding portions extending to at least one of areas between the plurality of signal wires, and one of the protruding portions is connected to the contact electrode.

The display apparatus may further include a second optical layer covering the second area of the second electrode.

The first optical layer and the second optical layer may be made of different materials.

The first optical layer may include light scattering particles.

A top surface of the second optical layer and a top surface of the first area of the second electrode may be coplanar.

A pattern of a black matrix may be formed on the first optical layer and the second optical layer.

The display apparatus may further include a plurality of bank patterns disposed between the substrate and the plurality of first electrodes.

The plurality of signal wires may extend between the plurality of bank patterns.

The contact electrode is disposed between the plurality of signal wires.

The second electrode may be divided in plural to be disposed in each pixel row, and the plurality of divided second electrodes may be electrically connected to the contact electrode, respectively.

The second electrode may include a third area extending to a side of the first optical layer and connecting the first area and the second area.

The display apparatus may further include an insulating layer disposed on the substrate; a plurality of connection wires disposed between the substrate and the insulating layer; and a pixel driving circuit connected to the plurality of connection wires, the plurality of connection wires may be electrically connected to the plurality of first electrodes and the contact electrode.

The plurality of light-emitting elements may be inorganic light-emitting diodes.

The pixel driving circuit is a driving driver.

According to one or more embodiments of the present disclosure, a display apparatus may include a plurality of first electrodes disposed on a substrate; a plurality of light-emitting elements disposed on the plurality of first electrodes; a first optical layer disposed between the plurality of light-emitting elements; a second electrode disposed on the plurality of light-emitting elements; and a second optical layer covering the first optical layer, the second electrode may include a first area disposed on the plurality of light-emitting elements and a second area extending outward from the first optical layer, the second optical layer may be disposed on the second area.

The first optical layer and the second optical layer may be made of different materials.

The first optical layer may include light scattering particles.

The display apparatus may further include a plurality of bank patterns disposed between the substrate and the plurality of first electrodes.

The display apparatus may further include a plurality of signal wires extending between the plurality of bank patterns and connected to the plurality of first electrodes.

The display apparatus may further include a contact electrode disposed on the substrate and electrically connected to the second electrode, the contact electrode may be disposed between the plurality of signal wires.

The second electrode may be divided in plural to be disposed in each pixel row, and the plurality of divided second electrodes may be electrically connected to the contact electrode, respectively.

The display apparatus may further include an insulating layer disposed on the substrate; a plurality of connection wires disposed between the substrate and the insulating layer; and a pixel driving circuit connected to the plurality of connection wires, the plurality of connection wires may be electrically connected to the plurality of first electrodes and the contact electrode.

The objects to be achieved by the present disclosure, the means for achieving the objects, and effects of the present disclosure described above do not specify essential features of the claims, and thus, the scope of the claims is not limited to the disclosure of the present disclosure.

Although the embodiments of the present disclosure have been described in more detail with reference to the accompanying drawings, the present disclosure is not limited thereto and may be embodied in many different forms without departing from the technical concept of the present disclosure. Therefore, the embodiments disclosed in the present disclosure are provided for illustrative purposes only and are not intended to limit the technical concept of the present disclosure. The scope of the technical concept of the present disclosure is not limited thereto. Therefore, it should be understood that the above-described embodiments are illustrative in all aspects and do not limit the present disclosure.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus comprising:
a plurality of first electrodes and a contact electrode disposed on a substrate;
a plurality of light-emitting elements disposed on the plurality of first electrodes;
a first optical layer disposed between the plurality of light-emitting elements;
a second electrode disposed on the plurality of light-emitting elements; and
a plurality of signal wires electrically connected to the plurality of first electrodes,
wherein the second electrode comprises a first area disposed on the plurality of light-emitting elements and a second area extending outward from the first optical layer and electrically connected to the contact electrode,
wherein the second area of the second electrode comprises protruding portions extending to at least one of areas between the plurality of signal wires, and
wherein one of the protruding portions is electrically connected to the contact electrode.

2. The display apparatus of claim 1, further comprising:
a second optical layer covering the second area of the second electrode.

3. The display apparatus of claim 2, wherein the first optical layer and the second optical layer are made of different materials.

4. The display apparatus of claim 3, wherein the first optical layer comprises light scattering particles.

5. The display apparatus of claim 2, wherein a top surface of the second optical layer and a top surface of the first area of the second electrode are coplanar.

6. The display apparatus of claim 5, wherein a pattern of a black matrix is formed on the first optical layer and the second optical layer.

7. The display apparatus of claim 1, further comprising:
a plurality of bank patterns disposed between the substrate and the plurality of first electrodes.

8. The display apparatus of claim 7, wherein the plurality of signal wires is extending between the plurality of bank patterns.

9. The display apparatus of claim 7, wherein the contact electrode is disposed between the plurality of signal wires.

10. The display apparatus of claim 2, wherein the second electrode is divided in plural to be disposed in each pixel row, and
a plurality of divided second electrodes are electrically connected to the contact electrode, respectively.

11. The display apparatus of claim 1, wherein the second electrode comprises a third area extending to a side of the first optical layer and connecting the first area and the second area.

12. The display apparatus of claim 1, further comprising:
an insulating layer disposed on the substrate;
a plurality of connection wires disposed between the substrate and the insulating layer; and
a pixel driving circuit electrically connected to the plurality of connection wires,
wherein the plurality of connection wires is electrically connected to the plurality of first electrodes and the contact electrode.

13. The display apparatus of claim 1, wherein the plurality of light-emitting elements are inorganic light-emitting diodes.

14. The display apparatus of claim 12, wherein the pixel driving circuit is a driver.

15. A display apparatus comprising:
a plurality of first electrodes disposed on a substrate;
a plurality of light-emitting elements disposed on the plurality of first electrodes;
a first optical layer disposed between the plurality of light-emitting elements;
a second electrode disposed on the plurality of light-emitting elements; and
a second optical layer covering the first optical layer,
wherein the second electrode comprises a first area disposed on the plurality of light-emitting elements and a second area extending outward from the first optical layer,
wherein the second optical layer is disposed on the second area,
wherein the second area of the second electrode comprises protruding portions extending to at least one of areas between a plurality of signal wires, and
wherein one of the protruding portions is electrically connected to a contact electrode.

16. The display apparatus of claim 15, wherein the first optical layer and the second optical layer are made of different materials.

17. The display apparatus of claim 16, wherein the first optical layer comprises light scattering particles.

18. The display apparatus of claim 15, further comprising:
a plurality of bank patterns disposed between the substrate and the plurality of first electrodes.

19. The display apparatus of claim 18, further comprising:
the plurality of signal wires extending between the plurality of bank patterns and connected to the plurality of first electrodes.

20. The display apparatus of claim 19, further comprising:
the contact electrode disposed on the substrate and electrically connected to the second electrode,
wherein the contact electrode is disposed between the plurality of signal wires.

21. The display apparatus of claim 20, wherein the second electrode is divided in plural to be disposed in each pixel row, and
a plurality of divided second electrodes are electrically connected to the contact electrode, respectively.

22. The display apparatus of claim 20, further comprising:
an insulating layer disposed on the substrate;
a plurality of connection wires disposed between the substrate and the insulating layer; and
a pixel driving circuit connected to the plurality of connection wires,
wherein the plurality of connection wires is electrically connected to the plurality of first electrodes and the contact electrode.

23. A display apparatus comprising:
a plurality of first electrodes on a substrate;
a plurality of light-emitting elements on the plurality of first electrodes;
a first optical layer disposed between the plurality of light-emitting elements;
a second electrode on the plurality of light-emitting elements;
a second optical layer adjacent to the first optical layer, the second optical layer having different materials from the first optical layer;
a contact electrode located in a first area spaced apart from the plurality of first electrodes when seen from a plan view, the contact electrode having a first surface and a second surface opposite the first surface; and
a plurality of wires on the substrate, at least one wire of the plurality of wires being electrically connected to the contact electrode,
wherein the second electrode extends from a light-emitting element of the plurality of light-emitting elements to the first area where the contact electrode is located,
wherein the second electrode includes a protruding portion that protrudes toward a first direction, and
wherein the protruding portion of the second electrode is adjacent to and contacts the second optical layer.

24. The display apparatus of claim 23, wherein the first direction is indicative of a direction towards the substrate.

25. The display apparatus of claim 24, wherein the protruding portion of the second electrode contacts the first surface of the contact electrode, and
wherein the second surface of the contact electrode faces the substrate.

26. The display apparatus of claim 24, further comprising a through electrode on the second optical layer,
wherein the through electrode has a first portion and a second portion,
wherein the first portion of the through electrode is disposed above the protruding portion of the second electrode, and
wherein the second portion of the through electrode is disposed beneath the protruding portion of the second electrode and contacts the first surface of the contact electrode.

27. The display apparatus of claim 23, wherein the first direction is indicative of a direction opposite of the substrate.

28. The display apparatus of claim 27, wherein the protruding portion of the second electrode is spaced apart from the first surface of the contact electrode, and
wherein the second surface of the contact electrode faces the substrate.

29. The display apparatus of claim 27, further comprising a through electrode on the second optical layer,
wherein the through electrode has a first portion and a second portion,
wherein the first portion of the through electrode is disposed above the protruding portion of the second electrode, and
wherein the second portion of the through electrode is disposed beneath the protruding portion of the second electrode and contacts the first surface of the contact electrode.
